(19) United States
(12) Patent Application Publication
(10) Pub. No.: US 2014/0353017 A1
(43) Pub. Date: Dec. 4, 2014

(54) PRINTED WIRING BOARD AND METHOD FOR MANUFACTURING THE SAME

(71) Applicant: IBIDEN CO., LTD., Ogaki (JP)

(72) Inventors: Kota NODA, Ogaki (JP); Nobuhisa KURODA, Ogaki (JP)

(73) Assignee: IBIDEN CO., LTD., Ogaki (JP)

(21) Appl. No.: 14/268,553

(22) Filed: May 2, 2014

(30) Foreign Application Priority Data
May 29, 2013 (JP) 2013-113356

(51) Int. Cl. H05K 1/18; H05K 3/30; H05K 1/03

(52) U.S. Cl. CPC H05K 1/184; H05K 1/0306; H05K 3/306; H05K 2203/1333; H05K 2203/166
USPC 174/257; 174/258; 29/837

(57) ABSTRACT

A wiring board includes a core substrate including an insulative substrate and a first inner conductive-circuit layer formed on first surface of the insulative substrate, an electronic component positioned in a penetrating hole formed in the insulative substrate and having a positive electrode terminal on first end portion and a negative electrode terminal on second end portion on the opposite side, a first interlayer insulative resin layer formed on first surface of the core such that the first insulative layer is positioned over the core and component in the penetrating hole, and an outer conductive-circuit layer formed on surface of the first insulative layer such that thicknesses of the first insulative layer between the outer conductive-circuit layer and the terminals are less than thickness of the first insulative layer between the first inner conductive-circuit layer and the outer conductive-circuit layer.

### CROSS-REFERENCE TO RELATED APPLICATIONS

The present application is based upon and claims the benefit of priority to Japanese Patent Application No. 2013-113356, filed May 29, 2013, the entire contents of which are incorporated herein by reference.

### BACKGROUND OF THE INVENTION

1. Field of the Invention

The present invention relates to a printed wiring board with a built-in electronic component and to a method for manufacturing the same. More specifically, the present invention proposes to provide technology for enabling secure control of operations of high-speed communications and multiple slave connections in LSIs and the like based on IIC (synchronous serial communication standards).

2. Description of Background Art

In a printed wiring board, leak current may be caused by insulation damage or tunneling effect. In such a case, if a conductive circuit is for signals, for example, signal transmission errors or the like may occur, thus resulting in problems such as difficulty in controlling operations of high-speed communications and slave connections in LSIs or the like.

### SUMMARY OF THE INVENTION

According to one aspect of the present invention, a wiring board includes a core substrate including an insulative substrate and a first inner conductive-circuit layer formed on a first surface of the insulative substrate, an electronic component positioned in a penetrating hole formed in the insulative substrate of the core substrate and having a positive electrode terminal on a first end portion and a negative electrode terminal on a second end portion on the opposite side with respect to the first end portion, a first interlayer insulative resin layer formed on a first surface of the core substrate such that the first interlayer insulative resin layer is positioned over the core substrate and the electronic component in the penetrating hole, and an outer conductive-circuit layer formed on a surface of the first interlayer insulative resin layer such that thicknesses of the first interlayer insulative resin layer between the outer conductive-circuit layer and the positive electrode terminal and between the outer conductive-circuit layer and negative electrode terminal are less than a thickness of the first interlayer insulative resin layer between the first inner conductive-circuit layer and the outer conductive-circuit layer.

According to another aspect of the present invention, a method for manufacturing a wiring board includes providing a core substrate including an insulative substrate and a first inner conductive-circuit layer formed on a first surface of the insulative substrate, positioning an electronic component in a penetrating hole formed in the insulative substrate of the core substrate such that the electronic component having a positive electrode terminal on a first end portion and a negative electrode terminal on a second end portion on the opposite side with respect to the first end portion is aligned with the core substrate, forming a first interlayer insulative resin layer on a first surface of the core substrate such that the first interlayer insulative resin layer is positioned over the core substrate and the electronic component in the penetrating hole, and forming an outer conductive-circuit layer on a surface of the first interlayer insulative resin layer such that thicknesses of the first interlayer insulative resin layer between the outer conductive-circuit layer and the positive electrode terminal and between the outer conductive-circuit layer and negative electrode terminal are less than a thickness of the first interlayer insulative resin layer between the first inner conductive-circuit layer and the outer conductive-circuit layer.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is a simplified cross-sectional view schematically showing a printed wiring board according to an embodiment of the present invention;

FIG. 2 is an enlarged planar view showing the vicinities of the MLCC terminals seen through the printed wiring board of the embodiment;

FIG. 3 is a cross-sectional view showing details of a printed wiring board according to another embodiment of the present invention;

FIG. 4 (a) to (e) are cross-sectional views showing steps of a method for manufacturing a printed wiring board according to an embodiment of the present invention; and

FIG. 5 (a) to (e) are cross-sectional views showing subsequent steps of the method for manufacturing a printed wiring board according to the embodiment.

### DETAILED DESCRIPTION OF THE EMBODIMENTS

The embodiments will now be described with reference to the accompanying drawings, wherein like reference numerals designate corresponding or identical elements throughout the various drawings.

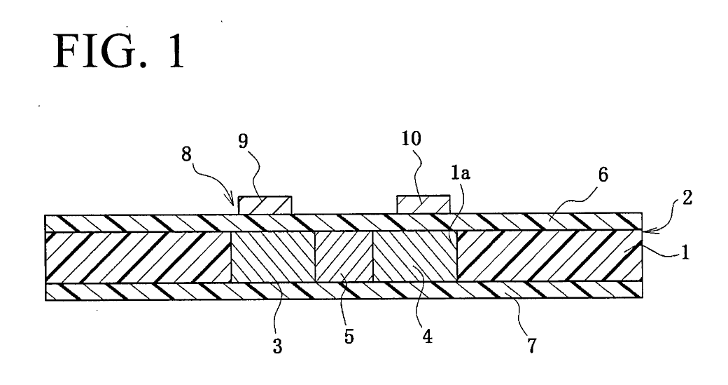

Referring to FIG. 1, numerical reference 1 in FIG. 1 indicates an insulative substrate made of a thermosetting resin material, numerical reference 2 indicates an insulative core substrate that includes insulative substrate 1 and inner conductive circuits (not shown) formed on upper- and lower-surface side surfaces of insulative substrate 1, and numerical reference (1a) indicates a penetrating hole with a predetermined size formed in a predetermined position of insulative substrate 1.

Here, in penetrating hole (1a) of insulative substrate 1, a capacitor (or condenser) as an electronic component, for example, multilayer ceramic capacitor (MLCC) 5, which has positive and negative electrode terminals (3, 4) on opposing end portions respectively, is aligned and positioned. Then, by sandwiching both core substrate 2 and MLCC 5, first interlayer insulative resin layer 6 laminated on the upper-surface side of the drawing and second interlayer insulative resin layer 7 laminated on the lower-surface side are respectively formed using a thermosetting resin material with a thickness of 20˜25 μm. At that time, MLCC 5 is fixed into penetrating hole (1a) by a resin material of first interlayer insulative resin layer 6 that flows into the space between MLCC 5 and the inner wall of penetrating hole (1a).

In addition, outer conductive-circuit layer 8 is formed on the surface of first or second interlayer insulative resin layer (6 or 7). Then, conductive circuits (9, 10) are formed on outer conductive-circuit layer 8 in vicinities that respectively include regions directly facing on or directly facing under positive and negative electrode terminals (3, 4) of MLCC 5, namely, in regions that respectively include positive and negative electrode terminals (3, 4) of MLCC 5, which are each enlarged outward by 20 μm, for example, from the measured planar outlines of terminals (3, 4). The polarity of conductive circuit (9 or 10) is set to be the same as that of its corresponding positive or negative electrode terminal (3 or 4) of MLCC 5.

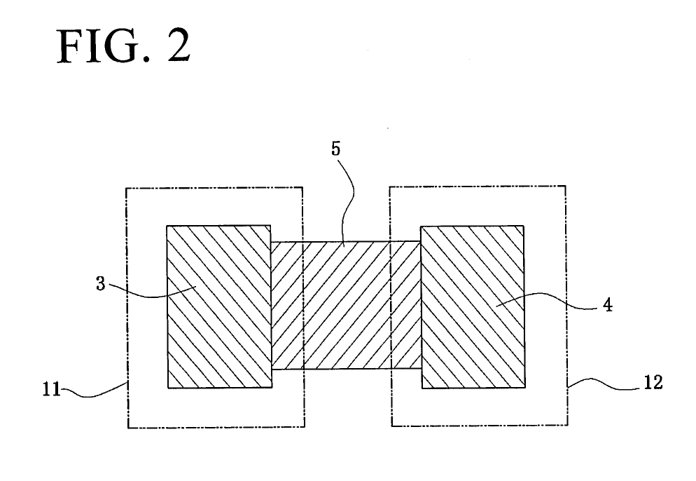

Namely, in the present embodiment, on the surface of first interlayer insulative resin layer 6, conductive circuits (9, 10) are each formed to have the same polarity as that of its corresponding terminal (3 or 4) in vicinity (11 or 12) of outer conductive-circuit layer 8 which includes the region directly on terminal (3 or 4) surrounded by a virtual line in the simplified planar view in FIG. 2. Outer conductive circuits (9, 10) are preferred to be set as power-source circuit 9 and ground circuit 10.

Also, in the present embodiment, in regions directly on positive and negative electrode terminals (3, 4) of MLCC 5, the thickness of first interlayer insulative resin layer 6 positioned between conductive circuits (9, 10) and insulative substrate 1 as well as MLCC 5 is less than that in the region directly on an inner conductive circuit on the upper surface of insulative substrate 1, although not shown in the drawing. That is because the resin material for first interlayer insulative resin layer 6 has flowed into the space between MLCC 5 and the inner wall of penetrating hole (1a).

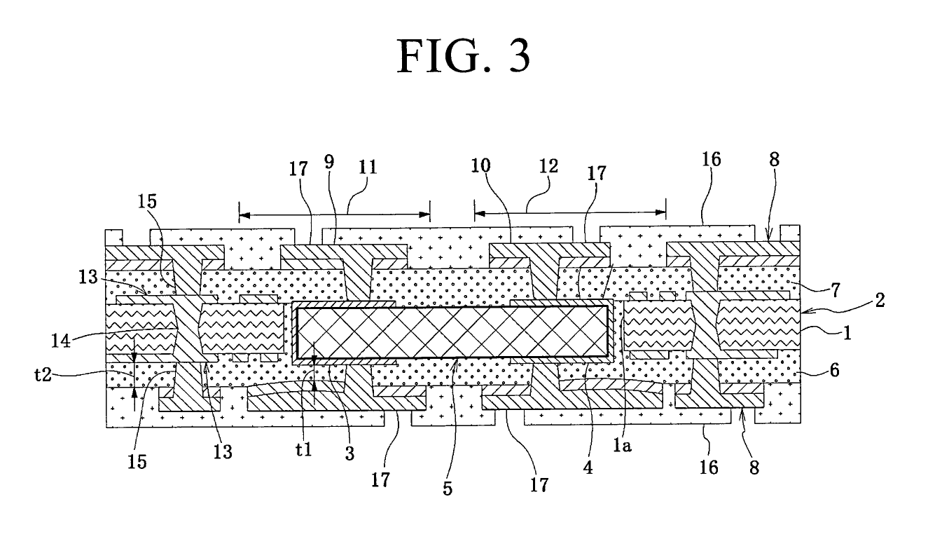

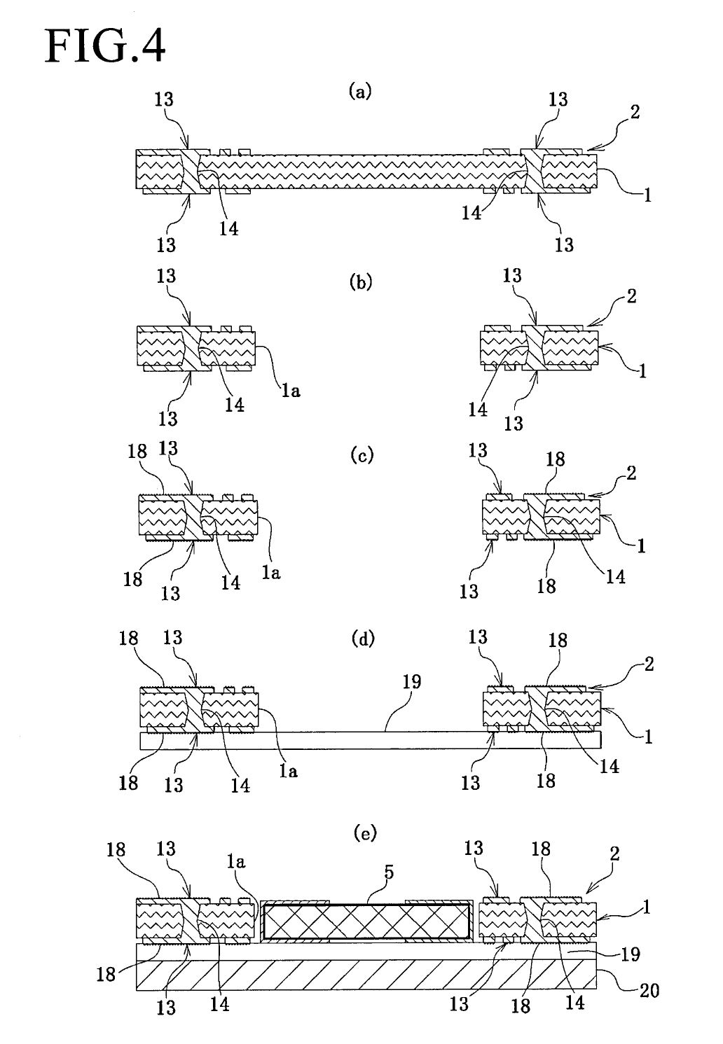

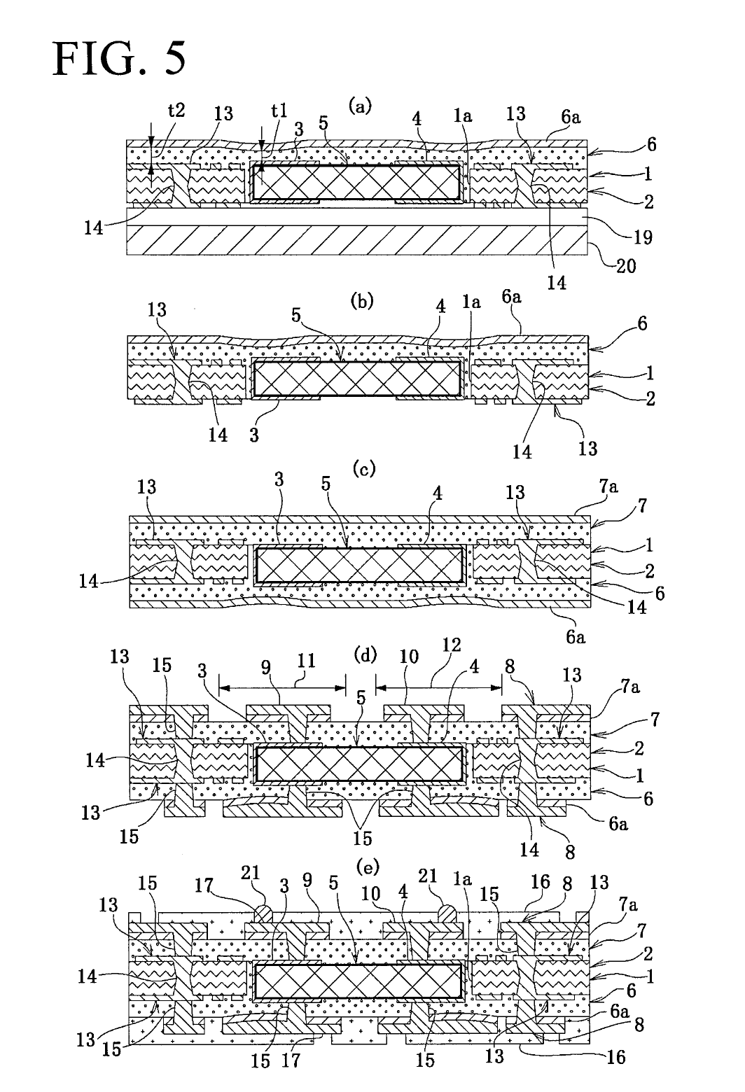

FIG. 3 is a cross-sectional view showing further detail of a printed wiring board according to another embodiment of the present invention. In the drawing, the same numerical reference number is applied to the same portion as that in the above embodiment. Also, for manufacturing a printed wiring board of the above embodiment, FIG. 4 (a) to 4(e) each show a cross-sectional view of a step in a printed wiring board manufacturing method according to an embodiment of the present invention, and FIG. 5 (a) to 5(e) each show a subsequent step in the printed wiring board manufacturing method according to the embodiment.

The printed wiring board of the present embodiment also has core substrate 2 having insulative substrate 1 with penetrating hole (1a) formed therein. In penetrating hole (1a) of insulative substrate 1, multilayer ceramic capacitor (MLCC) 5 as an electronic component having positive and negative electrode terminals (3, 4) on opposing end portions is aligned and positioned. Then, by sandwiching core substrate 2 and MLCC 5, first interlayer insulative resin layer 6 on the lower-surface side in the drawing and second interlayer insulative resin layer 7 on the upper-surface side are formed using a thermosetting resin material with a thickness of 20˜25 μm, for example. At that time, MLCC 5 is fixed in penetrating hole (1a) when the resin material of first interlayer insulative resin layer 6 flows to fill the space between MLCC 5 and the inner wall of penetrating hole 2.

In addition, outer conductive-circuit layer 8 is formed on the surfaces of first and second interlayer insulative resin layers (6, 7). Then, in vicinities that respectively include regions directly on or directly under positive and negative electrode terminals (3, 4) of MLCC 5, namely, in vicinities (11, 12), which are each enlarged outward by 20 μm, for example, from the measured planar outlines of positive and negative terminals (3, 4) of MLCC 5, conductive circuits (9, 10) are formed in outer conductive-circuit layer 8 on second interlayer insulative resin layer 7. Such conductive circuits (9, 10) are each set to have the same polarity as that of its corresponding positive or negative electrode terminal (3 or 4) of MLCC 5. Those conductive circuits (9, 10) are preferred to be set as power-source conductive circuit 9 and ground conductive circuit 10.

In a printed wiring board of the present embodiment, core substrate 2 has inner conductive-circuit layers 13 formed on the upper-surface and lower-surface side surfaces of insulative substrate 1 seen in the drawing as well as through-hole conductor 14 penetrating through insulative substrate 1 and electrically connecting those inner conductive-circuit layers 13. Inner conductive-circuit layers 13 and outer conductive-circuit layers 8 on first and second interlayer insulative resin layers (6, 7) are electrically connected by via holes 15 that penetrate through first and second interlayer insulative resin layers (6, 7) respectively. Also, first and second interlayer insulative resin layers (6, 7) and outer conductive-circuit layers 8 are covered by solder-resist layers 16. Portions of outer conductive-circuit layers 8 exposed by opening portions provided in solder-resist layer 16 are set as pads 17 to be connected to the outside.

FIG. 4 (a) to 4(e) show cross-sectional views of steps in a printed wiring board manufacturing method according to an embodiment of the present invention to manufacture a printed wiring board of the above embodiment, and FIG. 5 (a) to 5(e) show cross-sectional views of subsequent steps in the printed wiring board manufacturing method according to the embodiment.

In the manufacturing method of the present embodiment, first, as shown in FIG. 4(a), in insulative substrate 1, which is a double-sided copper-clad laminate made of a resin substrate sandwiched by copper foils, upper- and lower-surface side copper foils as seen in the drawing are etched to have a predetermined pattern so as to form inner conductive-circuit layers 13. Next, plating is filled in a penetrating hole formed in insulative substrate 1 using a laser to form through-hole conductor 14 that electrically connects inner conductive-circuit layers 13 on both surfaces. Then, as shown in FIG. 4(b), penetrating hole (1a) is formed by pressing a predetermined position of insulative substrate 1. Accordingly, core substrate 2 is formed.

Next, as shown in FIG. 4(c), roughened layer 18 is formed on the surface of inner conductive-circuit layer 13 on both surfaces of core substrate 2 to enhance adhesiveness of the interlayer insulative resin layers. Then, as shown in FIG. 4(d), core substrate 2 with penetrating hole (1a) formed in insulative substrate 1 is preliminarily fixed onto adhesive tape 19. Then, as shown in FIG. 4(e), MLCC 5 is mounted in a predetermined position on adhesive tape 19 in penetrating hole (1a).

Next, as shown in FIG. 5(a), adhesive tape 19 is placed on base board 20, and first interlayer insulative resin layer 6 made of resin film with copper foil (6a) laminated on one surface is laminated on the respective upper surfaces of core substrate 2 and MLCC 5 as seen in the drawing, and then first interlayer insulation resin layer 6 is adhered on the respective upper surfaces of core substrate 2 and MLCC 5 by hot pressing. At that time, MLCC 5 is preliminarily fixed by the resin material which is used to form first interlayer insulative resin layer 6 and which flows into the space between MLCC 5 and the inner wall surface of penetrating hole (1a) in insulative substrate 1 of core substrate 2.

At that time, thickness (t1) of first interlayer insulative resin layer 6 in the region directly on positive and negative electrode terminals (3, 4) of MLCC 5 is less than thickness (t2) in a region directly on the inner conductive circuit on the upper surface of insulative substrate 1. That is because the resin material of first interlayer insulative resin layer 6 has flowed into the space between MLCC 5 and the inner wall of penetrating hole (1a).

As shown in FIG. 5(b), adhesive tape 19 is removed, and then core substrate 2 and MLCC 5 are inverted. After first interlayer insulative resin layer 6 positioned on the lower side of core substrate 2 and MLCC 5 is placed on base board 20, the same one as shown in FIG. 4(e), second interlayer insulative resin layer 7 made of resin film with copper foil (7a) laminated on one surface, for example, is laminated on the respective upper surfaces of core substrate 2 and MLCC 5 as shown in FIG. 5(c). Then, by hot pressing, second interlayer insulative resin layer 7 is adhered on the respective upper surfaces of core substrate 2 and MLCC 5 so as to fix MLCC 5 thereon.

As shown in FIG. 5(d), outer conductive-circuit layer 8 with a predetermined pattern is formed on first and second interlayer insulative resin layers (6, 7) by forming electroless and electrolytic plated layers on copper foils (6a, 7a) and by etching copper foils (6a, 7a) and electroless and electrolytic plated layers. By filling plating conductor in penetrating holes formed in first and second interlayer insulative resin layers (6, 7) using a laser, for example, via holes 15 are formed to electrically connect inner conductive-circuit layer 13 and outer conductive-circuit layer 8 on both surface sides of core substrate 2.

Here, in vicinities (11, 12) which respectively include regions directly under terminals (3, 4) of MLCC 5 on the surface of first interlayer insulative resin layer 6, conductive circuits (9, 10) each having the same polarity as that of its corresponding terminal (3 or 4) are provided in outer conductive-circuit layer 8 formed on the surface of second interlayer insulative resin layer 7. Those conductive circuits (9, 10) are set as power-source circuit 9 and ground circuit 10.

Then, first interlayer insulative resin layer 6 and outer conductive-circuit layer 8 formed on resin layer 6, and second interlayer insulative resin layer 7 and outer conductive-circuit layer 8 formed on resin layer 7 are covered by solder-resist layer 16 made of insulative resin. The portions of outer conductive-circuit layers 8 exposed by opening portions of solder-resist layer 16 are set as pads 17 for connection with the outside. Accordingly, a printed wiring board of the present embodiment shown in FIG. 3 is completed.

As shown in FIG. 5(e), solder bump 21 is formed on pad 17, being connected through via hole 15 to terminal (3 or 4) of MLCC 5.

So far, the present invention has been described according to the embodiments with reference to the accompanying drawings. Conductive circuits (9, 10) may also be formed on the surface of first interlayer insulative resin layer 6. Also, a printed wiring board related to the present invention may be formed as a multilayer printed wiring board by further building up an interlayer insulative resin layer and an outer conductive-circuit layer on first and/or second interlayer insulative resin layers (6, 7) as needed. The electronic component may be a resistor, varistor, thermistor or the like instead of a capacitor (or condenser).

In response to demand for more-miniaturized and thinner printed wiring boards, if a first interlayer insulative resin layer directly on a capacitor (or a condenser) as a built-in electronic component is formed to be thinner, the conductive circuit on the first interlayer insulative resin layer and a terminal of the capacitor (condenser), for example, may be conducted due to leak current caused by insulation damage or tunneling effect. In such a case, if the conductive circuit is for signals, for example, signal transmission errors or the like may occur, thus resulting in problems such as difficulty in controlling operations of high-speed communications and slave connections in LSIs or the like.

A printed wiring board according to an embodiment of the present invention is capable of accurately and securely controlling operations of high-speed communications, and another embodiment of the present invention is directed to a method for manufacturing such a printed wiring board.

A printed wiring board according to an embodiment of the present invention has the following characteristics: The printed wiring board is formed to have a core substrate having an insulative substrate made of a thermosetting resin, for example, and inner conductive-circuit layers formed on the upper- and lower-surface side surfaces of the insulative substrate; an electronic component aligned in a penetrating hole formed in the insulative substrate of the core substrate and having a positive electrode terminal on one of the opposing end portions and a negative electrode terminal on the other; first and second interlayer insulative resin layers made of a thermosetting resin, for example, and provided respectively on both surfaces of the core substrate while sandwiching both the core substrate and the electronic component; and an outer conductive-circuit layer formed on the surface of the first or second interlayer insulative resin layer. In a region directly on or directly under the positive electrode terminal and negative electrode terminal of the electronic component, the thickness of the first or second interlayer insulative resin layer disposed between the outer conductive-circuit layer and the core substrate as well as the electronic component is less than the thickness in a region directly on or directly under the inner conductive-circuit layer. In the outer conductive-circuit layer, a conductive circuit positioned in the vicinity that includes the region directly on or directly under the positive electrode terminal of the electronic component has the same polarity as the positive electrode terminal, and a conductive circuit positioned in the vicinity that includes the region directly on or directly under the negative electrode terminal of the electronic component has the same polarity as the negative electrode terminal.

Here, “a vicinity that includes the region directly on or directly under a positive electrode terminal or a negative electrode terminal” indicates a region where the measurement of the planar outline of a positive electrode terminal or a negative electrode terminal of the electronic component is enlarged outward by 20 μm, for example.

Here, the electronic component is set as a capacitor (or a condenser), and the capacitor (or condenser) is set as a multilayer ceramic capacitor (MLCC). It is preferred to form a power-source conductive circuit and a ground conductive circuit in vicinities that respectively include regions directly on or directly under a positive electrode terminal and a negative electrode terminal of the electronic component and in the outer conductive-circuit layer which is positioned on the surface of the first or second interlayer insulative resin layer. In the first or second interlayer insulative resin layer, it is also preferred to form via holes that respectively connect the positive and negative electrode terminals and the conductive circuits each formed in the outer conductive-circuit layer to have the same polarity as that of its corresponding terminal.

A method for manufacturing a printed wiring board according to an embodiment of the present invention is characterized by the following. The manufacturing method includes: on an adhesive tape, a step for aligning an electronic component and a core substrate, the electronic component having a positive electrode terminal on one of the opposing end portions and a negative electrode terminal on the other, and the core substrate having an insulative substrate made of, for example, a thermosetting resin with a penetrating hole and having inner conductive-circuit layers provided on upper and lower surfaces of the insulative substrate; on the respective upper surfaces of the core substrate and the electronic component, a step for providing a first interlayer insulative resin layer made of a thermosetting resin, for example, while filling the resin material of the first interlayer insulative resin layer in the space between the electronic component and the inner wall of the penetrating hole in the insulative substrate of the core substrate; after removing the adhesive tape and then inverting the core substrate and the electronic component, a step for providing a second interlayer insulative resin layer, made of the same resin material as that for the first interlayer insulative resin layer, on the respective upper surfaces of the inverted core substrate and the electronic component; and on the surface of the first interlayer insulative resin layer, a step for providing an outer conductive-circuit layer. In the outer conductive-circuit layer, a conductive circuit positioned in a vicinity that includes the region directly under the positive electrode terminal of the electronic component is set to have the same polarity as the positive electrode terminal, and a conductive circuit positioned in a vicinity that includes the region directly under the negative electrode terminal of the electronic component is set to have the same polarity as the negative electrode terminal.

In the above method, in the vicinities that respectively include regions directly under a positive electrode terminal and a negative electrode terminal of the electronic component, a power-source conductive circuit and a ground conductive circuit are preferred to be formed respectively in the outer conductive-circuit layer on the surface of the first interlayer insulative resin layer.

A printed wiring board according to an embodiment of the present invention has, among the conductive circuits of the outer conductive-circuit layer formed on a surface of the first or second interlayer insulative resin layer, conductive circuits, positioned in vicinities that respectively include regions directly on or directly under the positive electrode terminal on one of the opposing end portions of the electronic component and the negative electrode terminal on the other, are each set to have the same polarity as its corresponding positive or negative electrode terminal, for example, and are respectively made to be a power-source conductive circuit and a ground conductive circuit. By so setting, even when an outer conductive circuit and a terminal of the electronic component are electrically connected because first and second interlayer insulative resin layers are made thinner in response to the demand for thinner printed wiring boards or the like, signal transmission failure will not occur, thus enabling secure and accurate control of operations of high-speed communications in LSIs or the like.

Here, the electronic component may be set as a capacitor (or condenser), and the capacitor (or condenser) may be set as a multilayer ceramic capacitor (MLCC). In addition, the electronic component may be set appropriately as a resistor, varistor, thermistor or the like.

In addition, when a power-source conductive circuit and a ground conductive circuit are formed in vicinities that respectively include regions directly on or directly under the positive and negative electrode terminals of the electronic component and in the outer conductive-circuit layer formed on the first or second interlayer insulative resin layer, any predetermined timing during the manufacturing process of the printed wiring board is selected for forming such conductive circuits. Also, even if electrical leakage occurs due to insulation damage or tunneling effect, signal transmission failure is prevented in a printed wiring board having such conductive circuits.

Using the manufacturing method of an embodiment of the present invention, the core substrate and an electronic component are aligned on an adhesive tape while the resin material for a first insulative resin layer is filled in the space between the electronic component and the inner wall of a penetrating hole formed in the insulative substrate of the core substrate. Thus, the relative position of the core substrate and the electronic component is ensured as designed, thereby simplifying the manufacturing process of a miniaturized thinner printed wiring board that does not cause signal transmission failure as described above.

Also, in such a manufacturing method, when a power-source conductive circuit and a ground conductive circuit are formed in vicinities that respectively include regions directly on or directly under positive electrode and negative electrode terminals of the electronic component as well as in the outer conductive-circuit layer on the upper surface of the first interlayer insulative resin layer, a printed wiring board that exhibits the aforementioned effects is manufactured in a simple, prompt way.

In a printed wiring board and a method for manufacturing the printed wiring board according to embodiments of the present invention, even if an outer conductive circuit and a terminal of an electronic component are conducted because first and second interlayer insulative resin layers are made thinner in response to demand for a thinner printed wiring board and the like, signal failure will not occur, thus enabling secure and accurate control of high-speed communication operations in LSIs or the like.

Obviously, numerous modifications and variations of the present invention are possible in light of the above teachings. It is therefore to be understood that within the scope of the appended claims, the invention may be practiced otherwise than as specifically described herein.

What is claimed is:

1. A wiring board, comprising:
a core substrate comprising an insulative substrate and a first inner conductive-circuit layer formed on a first surface of the insulative substrate;
an electronic component positioned in a penetrating hole formed in the insulative substrate of the core substrate and having a positive electrode terminal on a first end portion and a negative electrode terminal on a second end portion on an opposite side with respect to the first end portion;
a first interlayer insulative resin layer formed on a first surface of the core substrate such that the first interlayer insulative resin layer is positioned over the core substrate and the electronic component in the penetrating hole; and
an outer conductive-circuit layer formed on a surface of the first interlayer insulative resin layer such that thicknesses of the first interlayer insulative resin layer between the outer conductive-circuit layer and the positive electrode terminal and between the outer conductive-circuit layer and negative electrode terminal are less than a thickness of the first interlayer insulative resin layer between the first inner conductive-circuit layer and the outer conductive-circuit layer.

2. A wiring board according to claim 1, further comprising:
a second interlayer insulative resin layer formed on a second surface of the core substrate such that the second interlayer insulative resin layer is positioned over the core substrate and the electronic component on an opposite side with respect to the first surface of the core substrate,
wherein the core substrate includes a second inner conductive-circuit layer formed on a second surface of the insulative substrate on an opposite side with respect to the first surface of the insulative substrate.

3. A wiring board according to claim 1, wherein the outer conductive-circuit layer comprises a positive-polarity conductive circuit positioned directly facing the positive electrode terminal across the first interlayer insulative resin layer and a negative-polarity conductive circuit positioned directly facing the negative electrode terminal across the first interlayer insulative resin layer.

4. A wiring board according to claim 2, wherein the outer conductive-circuit layer comprises a positive-polarity conductive circuit positioned directly facing the positive electrode terminal across the first interlayer insulative resin layer and a negative-polarity conductive circuit positioned directly facing the negative electrode terminal across the first interlayer insulative resin layer.

5. A wiring board according to claim 1, further comprising:
a plurality of via conductors formed through the first interlayer insulative resin layer, wherein the outer conductive-circuit layer comprises a conductive circuit connected to the positive electrode terminal through one of the via conductors and positioned directly facing the positive electrode terminal across the first interlayer insulative resin layer and a conductive circuit connected to the negative electrode terminal through one of the via conductors and positioned directly facing the negative electrode terminal across the first interlayer insulative resin layer.

6. A wiring board according to claim 2, further comprising:
a plurality of via conductors formed through the first interlayer insulative resin layer, wherein the outer conductive-circuit layer comprises a conductive circuit connected to the positive electrode terminal through one of the via conductors and positioned directly facing the positive electrode terminal across the first interlayer insulative resin layer and a conductive circuit connected to the negative electrode terminal through one of the via conductors and positioned directly facing the negative electrode terminal across the first interlayer insulative resin layer.

7. A wiring board according to claim 1, wherein the outer conductive-circuit layer comprises a copper foil layer formed on the surface of the interlayer insulative resin layer.

8. A wiring board according to claim 1, further comprising:
a second interlayer insulative resin layer formed on a second surface of the core substrate such that the second interlayer insulative resin layer is positioned over the core substrate and the electronic component on an opposite side with respect to the first surface of the core substrate; and
a second outer conductive-circuit layer formed on a surface of the second interlayer insulative resin layer such that the second outer conductive-circuit layer includes a power supply circuit and a ground circuit,
wherein the core substrate includes a second inner conductive-circuit layer formed on a second surface of the insulative substrate on an opposite side with respect to the first surface of the insulative substrate.

9. A wiring board according to claim 1, further comprising:
a second interlayer insulative resin layer formed on a second surface of the core substrate such that the second interlayer insulative resin layer is positioned over the core substrate and the electronic component on an opposite side with respect to the first surface of the core substrate; and
a second outer conductive-circuit layer formed on a surface of the second interlayer insulative resin layer such that the second outer conductive-circuit layer includes a power supply circuit and a ground circuit,
wherein the core substrate includes a second inner conductive-circuit layer formed on a second surface of the insulative substrate on an opposite side with respect to the first surface of the insulative substrate, and the outer conductive-circuit layer comprises a positive-polarity conductive circuit positioned directly facing the positive electrode terminal across the first interlayer insulative resin layer and a negative-polarity conductive circuit positioned directly facing the negative electrode terminal across the first interlayer insulative resin layer.

10. A wiring board according to claim 1, further comprising:
a second interlayer insulative resin layer formed on a second surface of the core substrate such that the second interlayer insulative resin layer is positioned over the core substrate and the electronic component on an opposite side with respect to the first surface of the core substrate; and
a second outer conductive-circuit layer formed on a surface of the second interlayer insulative resin layer such that the second outer conductive-circuit layer includes a power supply circuit and a ground circuit,
wherein the core substrate includes a second inner conductive-circuit layer formed on a second surface of the insulative substrate on an opposite side with respect to the first surface of the insulative substrate, the outer conductive-circuit layer comprises a positive-polarity conductive circuit positioned directly facing the positive electrode terminal across the first interlayer insulative resin layer and a negative-polarity conductive circuit positioned directly facing the negative electrode terminal across the first interlayer insulative resin layer, and one of the positive-polarity conductive circuit and the positive-polarity conductive circuit is connected to one of the power supply circuit and the ground circuit through one of the positive electrode terminal, and the other one of the positive-polarity conductive circuit and the positive-polarity conductive circuit is connected to the other one of the power supply circuit and the ground circuit through the other one of the positive electrode terminal.

11. A wiring board according to claim 1, wherein the insulative substrate comprises a thermosetting resin, and the first interlayer insulative resin layer comprises a thermosetting resin.

12. A wiring board according to claim 1, wherein the electronic component is a multilayer ceramic capacitor.

13. A wiring board according to claim 11, wherein the electronic component is a multilayer ceramic capacitor.

14. A wiring board according to claim 1, wherein one of the positive-polarity conductive circuit and the positive-polarity conductive circuit is connected to one of a power supply circuit and a ground circuit, and the other one of the positive-polarity conductive circuit and the positive-polarity conductive circuit is connected to the other one of the power supply circuit and the ground circuit.

15. A method for manufacturing a wiring board, comprising:
providing a core substrate comprising an insulative substrate and a first inner conductive-circuit layer formed on a first surface of the insulative substrate;
positioning an electronic component in a penetrating hole formed in the insulative substrate of the core substrate such that the electronic component having a positive electrode terminal on a first end portion and a negative electrode terminal on a second end portion on an opposite side with respect to the first end portion is aligned with the core substrate;
forming a first interlayer insulative resin layer on a first surface of the core substrate such that the first interlayer insulative resin layer is positioned over the core substrate and the electronic component in the penetrating hole; and
forming an outer conductive-circuit layer on a surface of the first interlayer insulative resin layer such that thicknesses of the first interlayer insulative resin layer between the outer conductive-circuit layer and the positive electrode terminal and between the outer conductive-circuit layer and negative electrode terminal are less than a thickness of the first interlayer insulative resin layer between the first inner conductive-circuit layer and the outer conductive-circuit layer.

16. A method for manufacturing a wiring board according to claim 15, wherein the positioning of the electronic component includes attaching an adhesive tape on a second surface of the core substrate such that the adhesive tape closes an opening of the penetrating hole on the second surface of the core substrate and positioning the electronic component on the adhesive tape inside the penetrating hole of the insulative layer.

17. A method for manufacturing a wiring board according to claim 15, wherein the forming of the first interlayer insulative resin layer includes filling a resin derived from the first interlayer insulative resin layer into a space formed between the core substrate and the electronic component inside the penetrating hole of the insualtive substrate.

18. A method for manufacturing a wiring board according to claim 15, further comprising:
forming a second interlayer insulative resin layer on a second surface of the core substrate such that the second interlayer insulative resin layer is positioned over the core substrate and the electronic component,
wherein the core substrate includes a second inner conductive-circuit layer formed on a second surface of the insulative substrate on an opposite side with respect to the first surface of the insulative substrate.

19. A method for manufacturing a wiring board according to claim 15, wherein the forming of the outer conductive-circuit layer includes forming a positive-polarity conductive circuit positioned directly facing the positive electrode terminal across the first interlayer insulative resin layer and forming a negative-polarity conductive circuit positioned directly facing the negative electrode terminal across the first interlayer insulative resin layer.

20. A method for manufacturing a wiring board according to claim 15, wherein the insulative substrate comprises a thermosetting resin, the first interlayer insulative resin layer comprises a thermosetting resin, and the electronic component is a multilayer ceramic capacitor.
